(19) United States
(12) Patent Application Publication
(10) Pub. No.: US 2016/0190420 A1
(43) Pub. Date: Jun. 30, 2016

(54) ELECTRICAL AND THERMAL CONTACTS FOR BULK TETRAHEDRITE MATERIAL, AND METHODS OF MAKING THE SAME

(71) Applicant: Alphabet Energy, Inc., Hayward, CA (US)

(72) Inventors: Lindsay Miller, Berkeley, CA (US); John P. Reifenberg, Pleasanton, CA (US); Douglas Crane, El Cerrito, CA (US); Adam Lorimer, Walnut Creek, CA (US); Mario Aguirre, Livermore, CA (US); Jordan Chase, Oakland, CA (US); Matthew L. Scullin, San Francisco, CA (US)

(21) Appl. No.: 14/971,337

(22) Filed: Dec. 16, 2015

Related U.S. Application Data
(60) Provisional application No. 62/098,945, filed on Dec. 31, 2014.
(60) Provisional application No. 62/208,954, filed on Aug. 24, 2015.

(51) Int. Cl. H01L 35/32; H01L 35/16

(52) U.S. Cl. CPC H01L 35/32; H01L 35/16

(57) ABSTRACT

Under one aspect, a structure includes a tetrahedrite substrate; a first contact metal layer disposed over and in direct contact with the tetrahedrite substrate; and a second contact metal layer disposed over the first contact metal layer. A thermoelectric device can include such a structure. Under another aspect, a method includes providing a tetrahedrite substrate; disposing a first contact metal layer over and in direct contact with the tetrahedrite substrate; and disposing a second contact metal layer over the first contact metal layer. A method of making a thermoelectric device can include such a method.

### CROSS-REFERENCE TO RELATED APPLICATIONS

This application claims the benefit of the following applications, the entire contents of each of which are incorporated by reference herein:

U.S. Provisional Patent Application No. 62/098,945, filed Dec. 31, 2014 and entitled “ELECTRICAL AND THERMAL CONTACTS FOR BULK TETRAHEDRITE;” AND

U.S. Provisional Patent Application No. 62/208,954, filed Aug. 24, 2015 and entitled “ELECTRICAL AND THERMAL CONTACTS FOR BULK TETRAHEDRITE MATERIAL.”

### FIELD

This application relates to tetrahedrite material. In one example, the tetrahedrite material can be used in a thermoelectric device. It would be recognized that the invention has a far broader range of applicability.

### BACKGROUND

Tetrahedrite is a material that has been known for a long time in the mining industry as a naturally occurring mineral, but has only recently been appreciated for its thermoelectric properties, e.g., for use as a P-type thermoelectric material. Exemplary tetrahedrite materials that are known in the art include compounds of the formula (Cu,Ag)₁₂₋ₓMₓ(Sb,As,Te)₄(S,Se)₁₃, where M is a transition metal, or a suitable combination of transition metals, where x is between 0 and 2. Exemplary transition metals for use in tetrahedrite materials include any suitable combination of one or more of Zn, Fe, Mn, Hg, Co, Cd, and Ni, such as a combination of Zn and Ni.

For further details on exemplary tetrahedrite materials and exemplary methods of making such materials, see the following references, the entire contents of each of which are incorporated by reference herein:

International Publication No. WO 2014/008414, published Jan. 9, 2014 and entitled “THERMOELECTRIC MATERIALS BASED ON TETRAHEDRITE STRUCTURE FOR THERMOELECTRIC DEVICES;”

International Publication No. WO 2015/003157, published Jan. 8, 2015 and entitled “THERMOELECTRIC MATERIALS BASED ON TETRAHEDRITE STRUCTURE FOR THERMOELECTRIC DEVICES;”

Lu et al., “High performance thermoelectricity in earth-abundant compounds based on natural mineral tetrahedrites,” Advanced Energy Materials 3: 342-348 (2013);

Lu et al., “Natural mineral tetrahedrite as a direct source of thermoelectric materials,” Physical Chemistry Chemical Physics 15: 5762-5766 (2013); and

Lu et al., “Increasing the thermoelectric figure of merit of tetrahedrites by co-doping with nickel and zinc,” Chemistry of Materials 27: 408-413 (2015).

### SUMMARY

This application relates to tetrahedrite material. In one example, the tetrahedrite material can be used in a thermoelectric device. It would be recognized that the invention has a far broader range of applicability.

Under one aspect, a structure includes a tetrahedrite substrate; a first contact metal layer disposed over and in direct contact with the tetrahedrite substrate; and a second contact metal layer disposed over the first contact metal layer.

In some embodiments, the first contact metal layer includes a material selected from the group consisting of a refractory metal, a refractory metal alloyed with Ti or W, a stable sulfide, a stable sulfide alloyed with Ti or W, a stable refractory metal nitride, and a stable refractory metal carbide. The refractory metal can be selected from the group consisting of Mo, Nb, Ta, W, Re, Ti, V, Cr, Zr, Hf, Ru, Rh, Os, and Ir. The stable refractory metal nitride can be selected from the group consisting of TiN and TaN. The stable refractory metal carbide can be selected from the group consisting of TiC and WC. The stable sulfide can include La₂S₃.

In some embodiments, the second contact metal layer includes a noble metal. Additionally, or alternatively, the second contact metal layer can include a material selected from the group consisting of Au, Ag, Ni, Ni/Au, and Ni/Ag.

In some embodiments, the structure further includes a diffusion barrier metal layer disposed between the first contact metal layer and the second contact metal layer. The diffusion barrier metal layer can include a material selected from the group consisting of a refractory metal, a refractory metal alloyed with Ti or W, a stable sulfide, a stable nitride, a stable sulfide alloyed with Ti or W, and a stable nitride alloyed with Ti or W. The refractory metal can be selected from the group consisting of Mo, Nb, Ta, W, Re, Ti, V, Cr, Zr, Hf, Ru, Rh, Os, and Ir. The diffusion barrier metal layer can include a material selected from the group consisting of TiB₂, Ni, and MCrAlY where M is Co, Ni, or Fe. Additionally, or alternatively, the first contact metal layer and diffusion barrier metal layer can be deposited in alternating layers.

In some embodiments, the structure can include a braze or solder in direct contact with the second contact metal layer.

In some embodiments, the first contact metal layer includes a material selected from the group consisting of Ti, Ta, Cr, W, Nb, TiN, Mo, CrNi, and TaN.

The second contact metal layer can include a material selected from the group consisting of Ag, Ni, Ni/Au, and Ni/Ag.

In some embodiments, the structure further includes a diffusion barrier metal layer disposed between the first contact metal layer and the second contact metal layer. The diffusion barrier metal layer can include a material selected from the group consisting of Ti, Ta, Cr, W, Nb, TiN, TaN, CrNi, and Mo. Additionally, or alternatively, the first contact metal layer and diffusion barrier metal layer can be deposited in alternating layers.

In some embodiments, the structure can include a braze or solder in direct contact with the second contact metal layer.

In some embodiments, the first contact metal layer includes a material selected from the group consisting of TiW, TiB₂, Y, and MCrAlY where M is Co, Ni, or Fe.

In some embodiments, the second contact metal layer includes a material selected from the group consisting of Ni, Ag, and Au.

In some embodiments, the structure further includes a diffusion barrier metal layer disposed between the first contact metal layer and the second contact metal layer. The diffusion barrier metal layer can include a material selected from the group consisting of Ni, Ti, and W. Additionally, or alternatively, the first contact metal layer and diffusion barrier metal layer can be deposited in alternating layers.

In some embodiments, the structure can include a braze or solder in direct contact with the second contact metal layer.

Under another aspect, a thermoelectric device includes any of such structures.

Under another aspect, a method includes providing a tetrahedrite substrate; disposing a first contact metal layer over and in direct contact with the tetrahedrite substrate; and disposing a second contact metal layer over the first contact metal layer.

In some embodiments, at least one of the first contact metal layer and the second contact metal layer is disposed using physical vapor deposition or chemical vapor deposition. The physical vapor deposition can include sputtering or cathodic arc physical vapor deposition.

In some embodiments, said providing and disposing steps include co-sintering the first contact metal layer and the second contact metal layer in powder form with tetrahedrite powder.

In some embodiments, said providing and disposing steps include co-sintering thin foils of the first contact metal layer and the second contact metal layer with tetrahedrite powder.

In some embodiments, the first contact metal layer includes a material selected from the group consisting of a refractory metal, a refractory metal alloyed with Ti or W, a stable sulfide, a stable sulfide alloyed with Ti or W, a stable refractory metal nitride, and a stable refractory metal carbide. The refractory metal can be selected from the group consisting of Mo, Nb, Ta, W, Re, Ti, V, Cr, Zr, Hf, Ru, Rh, Os, and Ir. The stable refractory metal nitride can be selected from the group consisting of TiN and TaN. The stable refractory metal carbide can be selected from the group consisting of TiC and WC. The stable sulfide can include La₂S₃.

In some embodiments, the second contact metal layer includes a noble metal. In some embodiments, the second contact metal layer includes a material selected from the group consisting of Au, Ag, Ni, Ni/Au, and Ni/Ag.

In some embodiments, the method further includes disposing a diffusion barrier metal layer between the first contact metal layer and the second contact metal layer. In some embodiments, the diffusion barrier metal layer includes a material selected from the group consisting of a refractory metal, a refractory metal alloyed with Ti or W, a stable sulfide, a stable nitride, a stable sulfide alloyed with Ti or W, and a stable nitride alloyed with Ti or W. In some embodiments, the refractory metal is selected from the group consisting of Mo, Nb, Ta, W, Re, Ti, V, Cr, Zr, Hf, Ru, Rh, Os, and Ir. In some embodiments, the diffusion barrier metal layer includes a material selected from the group consisting of TiB₂, Ni, and MCrAlY where M is Co, Ni, or Fe. Additionally, or alternatively, the first contact metal layer and diffusion barrier metal layer can be deposited in alternating layers.

In some embodiments, the method further includes disposing a braze or solder in direct contact with the second contact metal layer.

In some embodiments, the first contact metal layer includes a material selected from the group consisting of Ti, Ta, Cr, W, Nb, TiN, Mo, CrNi, and TaN.

In some embodiments, the second contact metal layer includes a material selected from the group consisting of Ag, Ni, Ni/Au, and Ni/Ag.

In some embodiments, the method further includes disposing a diffusion barrier metal layer between the first contact metal layer and the second contact metal layer.

In some embodiments, the diffusion barrier metal layer includes a material selected from the group consisting of Ti, Ta, Cr, W, Nb, TiN, TaN, CrNi, and Mo. Additionally, or alternatively, the first contact metal layer and diffusion barrier metal layer can be deposited in alternating layers.

In some embodiments, the method further includes disposing a braze or solder in direct contact with the second contact metal layer.

In some embodiments, the first contact metal layer includes a material selected from the group consisting of TiW, TiB₂, Y, and MCrAlY where M is Co, Ni, or Fe.

In some embodiments, the second contact metal layer includes a material selected from the group consisting of Ni, Ag, and Au.

In some embodiments, the method further includes disposing a diffusion barrier metal layer between the first contact metal layer and the second contact metal layer. The diffusion barrier metal layer can include a material selected from the group consisting of Ni, Ti, and W. Additionally, or alternatively, the first contact metal layer and diffusion barrier metal layer can be deposited in alternating layers.

In some embodiments, the method further includes disposing a braze or solder in direct contact with the second contact metal layer.

Under another aspect, a method of making a thermoelectric device includes any of such methods.

### BRIEF DESCRIPTION OF DRAWINGS

FIG. 1A schematically illustrates a cross-section of an exemplary structure including metalized tetrahedrite, according to some embodiments of the present invention.

FIG. 1B schematically illustrates a cross-section of another exemplary structure including metalized tetrahedrite, according to some embodiments of the present invention.

FIG. 1C schematically illustrates a cross-section of another exemplary structure including metalized tetrahedrite, according to some embodiments of the present invention.

FIGS. 2A-2C schematically illustrate cross-sections of exemplary thermoelectric devices including structures including metalized tetrahedrite, according to some embodiments of the present invention.

FIG. 3 illustrates a flow of steps in an exemplary method of forming a structure including metalized tetrahedrite, according to some embodiments of the present invention.

### DETAILED DESCRIPTION

This application relates to tetrahedrite material. In one example, the tetrahedrite material can be used in a thermoelectric device. It would be recognized that the invention has a far broader range of applicability.

Tetrahedrite is a material that has been known for a long time in the mining industry as a naturally occurring mineral, but has only recently been appreciated for its thermoelectric properties. Because this material has only recently been used as a thermoelectric material, it is believed that all previous work has focused on improving its thermoelectric properties and that no work had been done prior to this invention on making electrical and thermal contact to the tetrahedrite. It is believed that prior to this invention it was not possible to actually use tetrahedrite in a thermoelectric system because it could not be electrically connected and/or would not survive heating to operation temperatures for more than a few hours. Embodiments of the invention described here facilitates or enables electrical and thermal contact to the tetrahedrite, even at operating temperatures for long periods of time, thus making the tetrahedrite commercially viable.

Making electrical contact to the tetrahedrite is believed not to be obvious because most metals fail to make contact to tetrahedrite due to one or more of several issues. Without wishing to be bound by any theory, it is believed that in one exemplary failure mode, certain metals react with the tetrahedrite and disappear into the material, destroying the thermoelectric properties by forming undesirable phases. Without wishing to be bound by any theory, it is believed that in another exemplary failure mode, certain metals can react with sulfur or antimony in the tetrahedrite to form a sulfur or antimony deficient region of tetrahedrite as well as a metal sulfide or metal antimonide layer. Without wishing to be bound by any theory, it is believed that certain metal sulfide or certain metal antimonide layers are detrimental since they are most often non-conductive, as it can be difficult to control the composition and/or phase and achieve a conductive sulfide or antimonide, and they can also cause adhesion problems since sulfides and antimonides tend to be chalky and/or brittle in consistency and/or can cause scaling and/or flaking. Without wishing to be bound by any theory, it is believed that in a third exemplary failure mode, certain metal layers do not adhere to the tetrahedrite surface. Without wishing to be bound by any theory, because of any combination of these three failure modes and potential difficulty in predicting which metals may succumb to these failures, choosing the first contact metal layer is believed to be non obvious.

An exemplary use or purpose of the present invention is to create contact with tetrahedrite material such that electrical (ohmic), thermal, and mechanical/metallurgical connection to the thermoelectric (TE) material (tetrahedrite material) between the material and a package or connector (shunt) can be achieved, as well as to create a diffusion barrier to inhibit or prevent the tetrahedrite from reacting with elements in the solder or braze or joining or connector (shunt) material.

Another exemplary use or purpose of the present invention is to create ohmic (e.g., low-resistance ohmic) and thermal contact with tetrahedrite material such that electrical and thermal connection to the material can be achieved, as well as create a diffusion barrier to inhibit or prevent the tetrahedrite from reacting with elements in the solder or braze or connector (shunt) materials and vice versa. Additionally or alternatively, and in some circumstances just as importantly, another exemplary use or purpose is to enable long term high temperature operation without a change in electrical or thermal interface resistance.

In some embodiments, the present invention specifies a recipe for the metallization of tetrahedrite and enables the use of tetrahedrite as, for example, a thermoelectric material, optionally over long periods of time at high temperatures. By metallization of tetrahedrite, or metalized tetrahedrite, it is meant that one or more layers that include metal are disposed on the tetrahedrite so as to provide stable thermal and electrical contact to the tetrahedrite. Without wishing to be bound by any theory, it is believed that without embodiments of the present invention, tetrahedrite is not commercially useful (e.g., as a thermoelectric material) because electrical and thermal contact to the material is insufficient, e.g., would be insufficient and would degrade significantly over time. It is believed that power and efficiency from the associated device (without implementation of the present tetrahedrite metallization) would be minimal or insufficient and/or degrade over time.

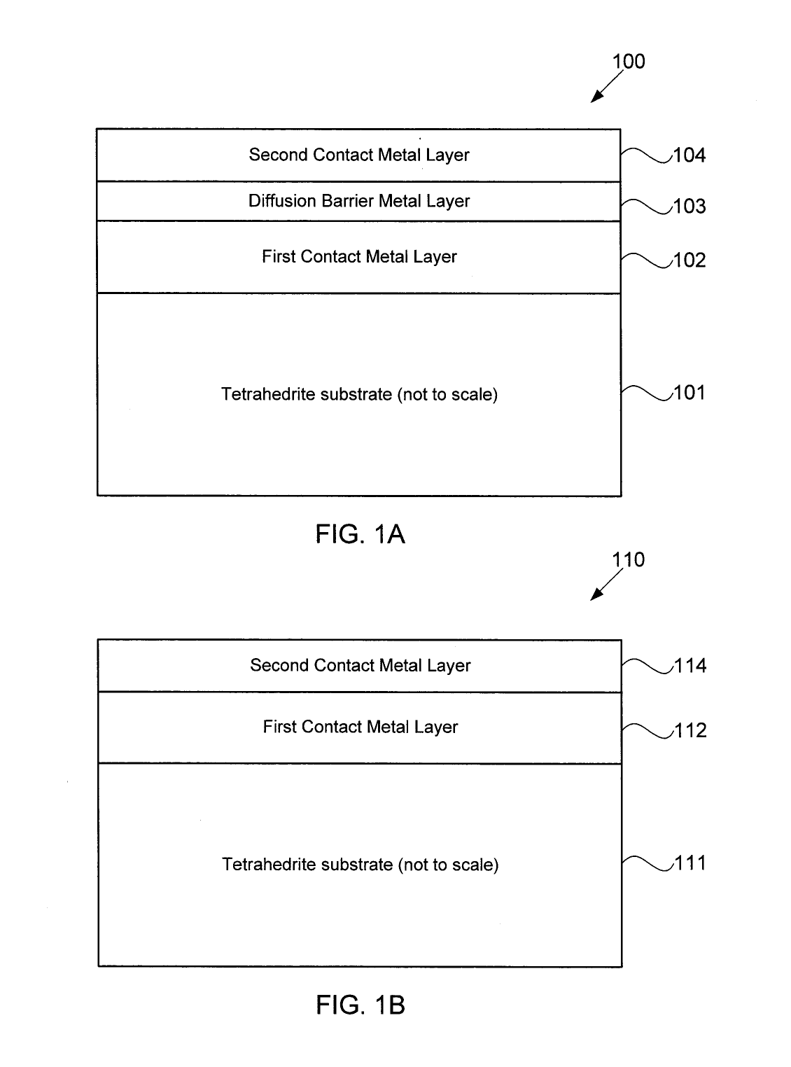

Some embodiments of the present invention include, or are composed of, a multilayer metal structure in which the first layer is designed to contact tetrahedrite, an optional intermediate layer serves as a diffusion barrier, and the second layer contacts a braze/solder or other joining material. For example, FIG. 1A schematically illustrates a cross-section of an exemplary structure including metalized tetrahedrite, according to some embodiments of the present invention. Structure 100 illustrated in FIG. 1A includes tetrahedrite substrate 101; first contact metal layer 102 disposed over and in direct contact with tetrahedrite substrate 101; optional diffusion barrier metal layer 103; and second contact metal layer 104 disposed over first contact metal layer 102 and (if provided) optional diffusion barrier metal layer 103. Tetrahedrite substrate 101 can have any suitable thickness, such as between 100 nm and 10 mm, or between 1 μm and 1 mm, or between 100 μm and 5 mm. First contact metal layer 102 can have any suitable thickness, such as between 10 nm and 10 μm or between 50 nm and 750 nm, or between 300 nm and 600 nm. Optional diffusion barrier metal layer 103 can have any suitable thickness, such as between 10 nm and 10 μm, or between 50 nm and 750 nm, or between 300 nm and 600 nm. Second contact metal layer 104 can have any suitable thickness, such as between 10 nm and 10 μm, or between 50 nm and 750 nm, or between 300 nm and 600 nm. An analogous arrangement of first contact metal layer 102, optional diffusion barrier metal layer 103, and second contact metal layer 104 optionally can be disposed on the other side of tetrahedrite substrate 101 so as to provide a sandwich type structure facilitating electrical contact to both sides of the tetrahedrite substrate 101. Note that in FIG. 1A and the other figures provided herein, the structures, tetrahedrite substrates, and various layers are not drawn to scale.

Illustratively, in some embodiments, first contact metal layer 102 includes a material selected from the group consisting of Ti, Ta, Cr, W, Nb, TiN, Mo, CrNi, and TaN, e.g., is or consists essentially of Ti, Ta, Cr, W, Nb, TiN, Mo, CrNi, or TaN. Illustratively, optional diffusion barrier metal layer 103 is disposed between the first contact metal layer and the second contact metal layer. Illustratively, diffusion barrier metal layer 103 includes a material selected from the group consisting of Ti, Ta, Cr, W, Nb, TiN, TaN, CrNi, and Mo, e.g., is or consists essentially of Ti, Ta, Cr, W, Nb, TiN, TaN, CrNi, or Mo. Illustratively, second contact metal layer 104 includes a material selected from the group consisting of Ag, Au, Ni, Ni/Au, and Ni/Ag, e.g., is or consists essentially of Ag or Au or Ni or Ni/Au of Ni/Ag or Ni/Au or Ni/Ag. In another embodiment, or in any embodiment using any suitable combination of any such materials or other materials, first contact metal layer 102 and diffusion barrier metal layer 103 are deposited in alternating layers in a manner such as described below with reference to FIG. 1C. Illustratively, first contact layer 102 and barrier layer 103 are both very thin and are deposited in alternating layers for tens or hundreds of layers. In another embodiment, or in any embodiment using any suitable combination of any such materials or other materials, first contact layer 102 also serves as the diffusion barrier. That is, the diffusion barrier function of diffusion barrier metal layer 103 optionally instead can be provided by first contact metal layer 102, e.g., in a manner such as described below with reference to FIG. 1B. In another embodiment, or in any embodiment using any suitable combination of any such materials or other materials, second layer 104 contacts a braze/solder or other joining material. For example, structure 100 can include or can be in contact with a braze or solder (not specifically illustrated in FIG. 1A) that is in direct contact with second contact metal layer 104.

Illustratively, in some embodiments, first contact metal layer 102 is, consists essentially of, or includes a material selected from the group consisting of TiW, TiB₂, Y, and MCrAlY where M is Co, Ni, or Fe, e.g., is TiW, TiB₂, MCrAlY (where M is Co, Ni, or Fe) or Y. Illustratively, optional diffusion barrier metal layer 103 is disposed between first contact metal layer 102 and second contact metal layer 104. Illustratively, diffusion barrier metal layer 103 includes a material selected from the group consisting of Ni, Ti, and W, e.g., is or consists essentially of Ni, Ti, or W. Illustratively, second contact metal layer 104 includes a material selected from the group consisting of Ni, Ag, and Au, e.g., is or consists essentially of Ni, Ag, and/or Au. In another embodiment, or in any embodiment using any suitable combination of any such materials or other materials, first contact metal layer 102 and diffusion barrier metal layer 103 are deposited in alternating layers in a manner such as described below with reference to FIG. 1C. Illustratively, first contact layer 102 and barrier layer 103 are both very thin and are deposited in alternating layers for several or tens of layers before adding second contact layer 104. In another embodiment, or in any embodiment using any suitable combination of any such materials or other materials, first contact layer 102 also serves as the diffusion barrier. That is, the diffusion barrier function of diffusion barrier metal layer 103 optionally instead can be provided by first contact metal layer 102, e.g., in a manner such as described below with reference to FIG. 1B. In another embodiment, or in any embodiment using any suitable combination of any such materials or other materials, second layer 104 contacts a braze/solder or other joining material. For example, structure 100 can include or be in contact with a braze or solder (not specifically illustrated in FIG. 1A) that is in direct contact with second contact metal layer 104.

Illustratively, in some embodiments, first contact metal layer 102 includes a material selected from the group consisting of a refractory metal, a refractory metal alloyed with Ti or W, a stable sulfide, a stable sulfide alloyed with Ti or W, a stable refractory metal nitride, and a stable refractory metal carbide, e.g., is or consists essentially of a refractory metal, a refractory metal alloyed with Ti or W, a stable sulfide, a stable sulfide alloyed with Ti or W, a stable refractory metal nitride, or a stable refractory metal carbide. Illustratively, the alloys can have weight percents of Ti or Win the range of about 1-99%, or 2-50%, or 5-20%. In some embodiments, the refractory metal is selected from the group consisting of Mo, Nb, Ta, W, Re, Ti, V, Cr, Zr, Hf, Ru, Rh, Os, and Ir. In some embodiments, the stable refractory metal nitride is selected from the group consisting of TiN and TaN. In some embodiments, the stable refractory metal carbide is selected from the group consisting of TiC and WC. In some embodiments, the stable sulfide includes La₂S₃. Optionally, diffusion barrier metal layer 103 is disposed between the first contact metal layer and the second contact metal layer. Illustratively, diffusion barrier metal layer 103 can include a material selected from the group consisting of a refractory metal, a refractory metal alloyed with Ti or W, a stable sulfide, a stable nitride, a stable sulfide alloyed with Ti or W, and a stable nitride alloyed with Ti or W, e.g., is or consists essentially of a refractory metal, a refractory metal alloyed with Ti or W, a stable sulfide, a stable nitride, a stable sulfide alloyed with Ti or W, or a stable nitride alloyed with Ti or W. Illustratively, the refractory metal is selected from the group consisting of Mo, Nb, Ta, W, Re, Ti, V, Cr, Zr, Hf, Ru, Rh, Os, and Ir. Illustratively, diffusion barrier metal layer 103 is, consists essentially of, or includes a material selected from the group consisting of TiB₂, Ni, and MCrAlY where M is Co, Ni, or Fe. Illustratively, second contact metal layer 104 includes a noble metal, e.g., is or consists essentially of a noble metal. Noble metals are those generally considered to be resistant to corrosion and oxidation in moist air, and include Ru, Rh, Pd, Ag, Os, Ir, Pt, and Au, e.g., include Au, Ag, Pd, and Pt. In some embodiments, second contact metal layer 104 includes a material selected from the group consisting of Au, Ag, Ni, Ni/Au, and Ni/Ag, e.g., is or consists essentially of Au, Ag, Ni, Ni/Au, or Ni/Ag. In another embodiment, or in any embodiment using any suitable combination of any such materials or other materials, first contact metal layer 102 and diffusion barrier metal layer 103 are deposited in alternating layers in a manner such as described below with reference to FIG. 1C. Illustratively, first contact layer 102 and barrier layer 103 are both very thin and are deposited in alternating layers for several or tens of layers before adding second contact layer 104. In another embodiment, or in any embodiment using any suitable combination of any such materials or other materials, first contact layer 102 also serves as the diffusion barrier. That is, the diffusion barrier function of diffusion barrier metal layer 103 optionally instead can be provided by first contact metal layer 102, e.g., in a manner such as described below with reference to FIG. 1B. In another embodiment, or in any embodiment using any suitable combination of any such materials or other materials, second layer 104 contacts a braze/solder or other joining material. For example, structure 100 can include or be in contact with a braze or solder (not specifically illustrated in FIG. 1A) that is in direct contact with second contact metal layer 104.

Other configurations suitably can be used. For example, as noted above, first contact metal layer 102 optionally can serve as a diffusion barrier. FIG. 1B schematically illustrates a cross-section of another exemplary structure including metalized tetrahedrite, according to some embodiments of the present invention. Structure 110 illustrated in FIG. 1B includes tetrahedrite substrate 111 which can be configured similarly as tetrahedrite substrate 101 described herein with reference to FIG. 1A; first contact metal layer 112 disposed over and in direct contact with tetrahedrite substrate 111 and which can be configured similarly as first contact metal layer 102 described herein with reference to FIG. 1A; and second contact metal layer 114 disposed over and in direct contact with first contact metal layer 112 and which can be configured similarly as second contact metal layer 104 described herein with reference to FIG. 1A. Tetrahedrite substrate 111 can have any suitable thickness, such as between 100 nm and 10 mm, or between 1 μm and 1 mm, or between 100 μm and 5 mm. First contact metal layer 112 can have any suitable thickness, such as between 10 nm and 10 μm, or between 50 nm and 750 nm, or between 300 nm and 600 nm. Second contact metal layer 114 can have any suitable thickness, such as between 10 nm and 10 μm, or between 50 nm and 750 nm, or between 300 nm and 600 nm. An analogous arrangement of first contact metal layer 112 and second contact metal layer 114 optionally can be disposed on the other side of tetrahedrite substrate 111 so as to provide a sandwich type structure facilitating electrical contact to both sides of the tetrahedrite substrate 111.

In another example, as noted above, first contact metal layer 102 and diffusion barrier metal layer 103 can both be very thin and can be deposited in alternating layers for several or tens or hundreds of layers before adding second contact metal layer 104. FIG. 1C schematically illustrates a cross-section of another exemplary structure including metalized tetrahedrite, according to some embodiments of the present invention. Structure 120 illustrated in FIG. 1C includes tetrahedrite substrate 121 which can be configured similarly as tetrahedrite substrate 101 described herein with reference to FIG. 1A; multilayer 125 disposed over and in direct contact with tetrahedrite substrate 121; and second contact metal layer 124 disposed over and in direct contact with multilayer 125 and which can be configured similarly as second contact metal layer 104 described herein with reference to FIG. 1A. Multilayer 125 can include alternating layers of a first contact metal which can be configured similarly as first contact metal layer 102 described herein with reference to FIG. 1A and layers of a diffusion barrier metal which can be configured similarly as diffusion barrier metal layer 103 described herein with reference to FIG. 1A. Tetrahedrite substrate 121 can have any suitable thickness, such as between 100 nm and 10 mm, or between 1 μm and 1 mm, or between 100 μm and 5 mm. Multilayer 125 can have any suitable thickness, such as between 10 nm and 10 μm or between 50 nm and 750 nm, or between 300 nm and 600 nm. Within multilayer 125, each first contact metal layer can have any suitable thickness, such as between 1 nm and 100 nm, or between 5 nm and 75 nm, or between 30 nm and 60 nm. Within multilayer 125, each diffusion barrier metal layer can have any suitable thickness, such as between 1 nm and 100 nm, or between 5 nm and 75 nm, or between 30 nm and 60 nm. Second contact metal layer 124 can have any suitable thickness, such as between 10 nm and 10 μm or between 50 nm and 750 nm, or between 300 nm and 600 nm. An analogous arrangement of multilayer 125 and second contact metal layer 124 optionally can be disposed on the other side of tetrahedrite substrate 121 so as to provide a sandwich type structure facilitating electrical contact to both sides of the tetrahedrite substrate 121.

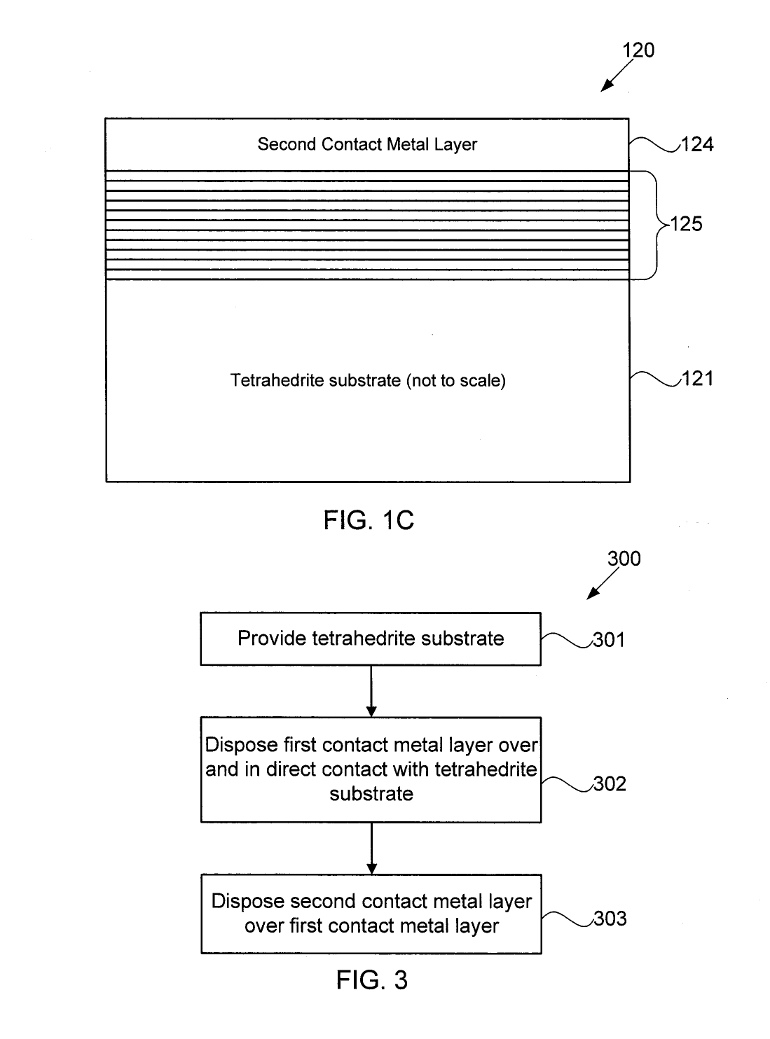

Any of the structures provided herein, e.g., such as described above with reference to FIGS. 1A-1C, can be included within a thermoelectric device. For example, FIGS. 2A-2C schematically illustrate cross-sections of exemplary thermoelectric devices including an exemplary structure including metalized tetrahedrite, according to some embodiments of the present invention. FIG. 2A is a simplified diagram illustrating an exemplary thermoelectric device including a structure that includes metalized tetrahedrite material such as described herein with reference to FIGS. 1A-1C, according to certain embodiments of the present invention. Thermoelectric device 20 includes first electrode 21, second electrode 22, third electrode 23, N-type thermoelectric material 24, and structure 25 that includes metalized tetrahedrite that can have a structure such as described herein with reference to FIGS. 1A-1C. A second contact metal layer of structure 25 that is disposed on a first side of the tetrahedrite substrate can be coupled to first electrode 21 via braze, solder, or other joining material, and another second contact metal layer of structure 25 that is disposed on a second side of the tetrahedrite substrate can be coupled to third electrode 23 via braze, solder, or other joining material. N-type thermoelectric material 24 can be disposed between first electrode 21 and second electrode 22. Structure 25 can be disposed between first electrode 21 and third electrode 23. Exemplary thermoelectric materials suitable for use as thermoelectric material 24 include, but are not limited to, silicon-based thermoelectric materials, lead telluride (PbTe), bismuth telluride (BiTe), scutterudite, clathrates, silicides, and tellurium-silver-germanium-antimony (TeAgGeSb, or “TAGS”). N-type thermoelectric material 24 can be in the form of a bulk material, or alternatively can be provided in the form of a nanostructure such as a nanocrystal, nanowire, or nanoribbon. Use of nanocrystals, nanowires, and nanoribbons in thermoelectric devices is known. Exemplary forms of silicon that can be used as thermoelectric materials include low dimension silicon material (thin film, nanostructured silicon powder, mesoporous particles, and the like), raw silicon material, wafer, and sintered structures in at least partially bulk form. In one nonlimiting, illustrative embodiment, material 24 can be based on sintered silicon nanowires prepared in a manner analogous to that described in US Patent Publication No. 2014/0116491 to Reifenberg et al., the entire contents of which are incorporated by reference herein.

Thermoelectric device 20 can be configured to generate an electric current flowing between first electrode 21 and second electrode 24 through N-type thermoelectric material 24 based on the first and second electrodes being at different temperatures than one another. For example, first electrode 21 can be in thermal and electrical contact with N-type thermoelectric material 24, with structure 25, and with a first body, e.g., heat source 26. Second electrode 22 can be in thermal and electrical contact with N-type thermoelectric material 24, and with a second body, e.g., heat sink 27. Third electrode 23 can be in thermal and electrical contact with structure 25 and with the second body, e.g., heat sink 27. Accordingly, N-type thermoelectric material 24 and structure 25 can be configured electrically in series with one another, and thermally in parallel with one another between the first body, e.g., heat source 26, and the second body, e.g., heat sink 27. Note that heat source 26 and heat sink 27 can be, but need not necessarily be, considered to be part of thermoelectric device 20.

N-type thermoelectric material 24 can be considered to provide an N-type thermoelectric leg of device 20, and structure 25 can be considered to provide a P-type thermoelectric leg of device 20. Responsive to a temperature differential or gradient between the first body, e.g., heat source 26, and the second body, e.g., heat sink 27, electrons (e−) flow from first electrode 21 to second electrode 22 through first N-type thermoelectric material 24, and holes (h+) flow from first electrode 21 to third electrode 23 through structure 25, thus generating a current. In one illustrative example, N-type thermoelectric material 24 and structure 25 are connected electrically to each other and thermally to first body 26, e.g., heat source, via first electrode 21. As heat flows from first body 26 to second body 27, e.g., heat sink, through N-type thermoelectric material 24 and structure 25 in parallel, negative electrons travel from the hot to cold end of the N-type thermoelectric material 24 and positive holes travel from the hot to cold end of structure 25. An electrical potential or voltage between electrodes 28 and 29 is created by having each material leg in a temperature gradient with electric current flow created as the N-type thermoelectric material 24 and structure 25 are connected together electrically in series and thermally in parallel.

The current generated by device 20 can be utilized in any suitable manner. For example, second electrode 22 can be coupled to anode 28 via a suitable connection, e.g., an electrical conductor, and third electrode 23 can be coupled to cathode 29 via a suitable connection, e.g., an electrical conductor. Anode 28 and cathode 29 can be connected to any suitable electrical device so as to provide a voltage potential or current to such device. Exemplary electrical devices include batteries, capacitors, motors, and the like. For example, FIG. 2B is a simplified diagram illustrating an alternative thermoelectric device including a silicon-based thermoelectric material including one or more isoelectronic impurities, according to certain embodiments of the present invention. Device 20′ illustrated in FIG. 2B is configured analogously to device 20 illustrated in FIG. 2A, but including alternative anode 28′ and alternative cathode 29′ that are respectively coupled to first and second terminals of resistor 30. Resistor 30 can be a stand-alone device or can be a portion of another electrical device to which anode 28′ and cathode 29′ can be coupled. Exemplary electrical devices include batteries, capacitors, motors, and the like.

Other types of thermoelectric devices suitably can include the present metalized tetrahedrite materials. For example, FIG. 2C is a simplified diagram illustrating another exemplary alternative thermoelectric device including a structure including metalized tetrahedrite such as described herein with reference to FIGS. 1A-1C, according to certain embodiments of the present invention. Thermoelectric device 20″ includes first electrode 21″, second electrode 22″, third electrode 23″, N-type thermoelectric material 24″, and structure 25″. N-type thermoelectric material 24″ can be disposed between first electrode 21″ and second electrode 22″ and include materials such as described above with reference to FIG. 2A. A second contact metal layer of structure 25″ that is disposed on a first side of the tetrahedrite substrate can be coupled to first electrode 21″ via braze, solder, or other joining material, and another second contact metal layer of structure 25″ that is disposed on a second side of the tetrahedrite substrate can be coupled to third electrode 23″ via braze, solder, or other joining material.

Thermoelectric device 20″ can be configured to pump heat from first electrode 21″ to second electrode 24″ through N-type thermoelectric material 24″ based on a voltage applied between the first and second electrodes. For example, first electrode 21″ can be in thermal and electrical contact with N-type thermoelectric material 24″, with structure 25″, and with a first body 26″ from which heat is to be pumped. Second electrode 22″ can be in thermal and electrical contact with N-type thermoelectric material 24″, and with a second body 27″ to which heat is to be pumped. Third electrode 23″ can be in thermal and electrical contact with structure 25″ and with the second body 27″ to which heat is to be pumped. Accordingly, N-type thermoelectric material 24″ and structure 25″ can be configured electrically in series with one another, and thermally in parallel with one another between the first body 26″ from which heat is to be pumped, and the second body 27″ to which heat is to be pumped. Note that first body 26″ and second body 27″ can be, but need not necessarily be, considered to be part of thermoelectric device 20″.

In the exemplary embodiment illustrated in FIG. 2C, N-type thermoelectric material 24″ can be considered to provide an N-type thermoelectric leg of device 20″, and structure 25″ can be considered to provide a P-type thermoelectric leg of device 20″. Second electrode 22″ can be coupled to cathode 28″ of battery or other power supply 30″ via a suitable connection, e.g., an electrical conductor, and third electrode 23″ can be coupled to anode 29″ of battery or other power supply 30″ via a suitable connection, e.g., an electrical conductor. Responsive to a voltage applied by battery or other power supply 30″ between second electrode 22″ and third electrode 23″, electrons (e−) flow from first electrode 21″ to second electrode 22″ through N-type thermoelectric material 24″, and holes (h+) flow from first electrode 21″ to third electrode 23″ through structure 25″, thus pumping heat from first body 26″ to second body 27″. In one illustrative example, N-type thermoelectric material 24″ and structure 25″ are connected electrically to each other and to first body 26″ from which heat is pumped, via first electrode 21″. As electric current is injected from battery or other power supply 30″ into the couple flowing from structure 25″ to material 24″, which are electrically in series and thermally in parallel, negative electrons of material 24″ and positive holes of structure 25″ travel from one end of the corresponding thermoelectric material to the other. Heat is pumped in the same direction as the electron and hole movement, creating a temperature gradient. If the direction of the electrical current is reversed, so will the direction of electron and hole movement, and heat pumping. The pumping of heat from first body 26″ to second body 27″ suitably can be used to cool first body 26″. For example, first body 26″ can include a computer chip.

As discussed above and as further emphasized here, FIGS. 2A-2C are merely examples, which should not unduly limit the claims. One of ordinary skill in the art would recognize many variations, alternatives, and modifications. For example, the present metalized tetrahedrite materials can be used in any suitable thermoelectric or non-thermoelectric device. Additionally, the embodiments illustrated in FIGS. 2A-2C suitably can use materials other than those specifically described above with reference to FIGS. 1A-1C.

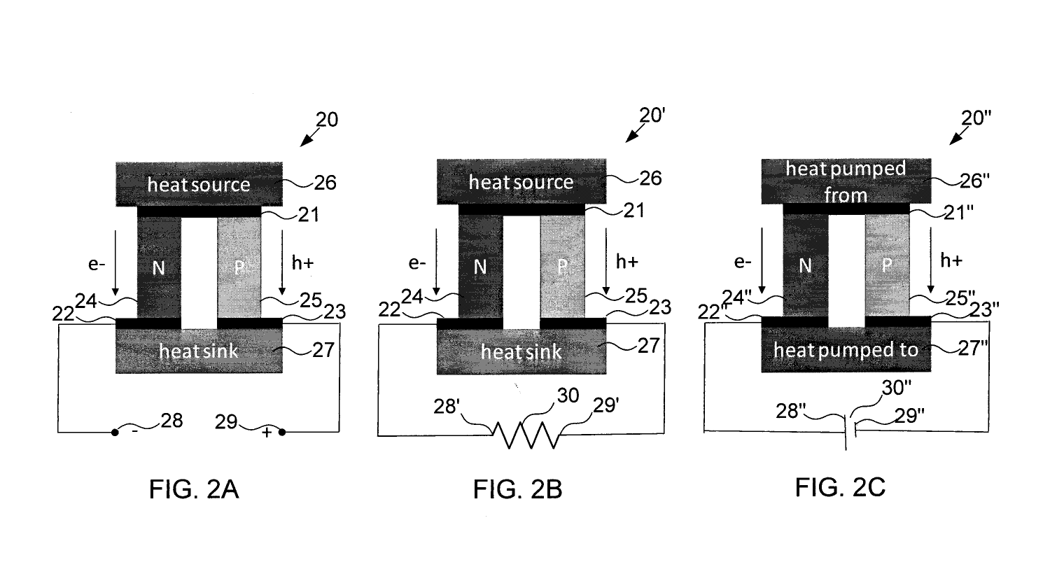

Structures such as described herein with reference to FIGS. 1A-1C can be made using any suitable sequence and combination of steps. For example, FIG. 3 illustrates a flow of steps in an exemplary method of forming a structure including metalized tetrahedrite, according to some embodiments of the present invention. Method 300 includes providing a tetrahedrite substrate (301). Method 300 also includes disposing a first contact metal layer over and in direct contact with the tetrahedrite substrate (302). Method 300 also includes disposing a second contact metal layer over the first contact metal layer (303). The second contact metal layer can be, but need not necessarily be, in direct contact with the first contact metal layer. For example, the second contact metal layer optionally can be disposed over a diffusion barrier metal layer that is disposed over the first contact metal layer.

Steps 301, 302, and 303 can be performed in any suitable order and using any suitable combination of techniques and materials. For example, in some embodiments, at least one of the first contact metal layer and the second contact metal layer is disposed using physical vapor deposition (PVD) or chemical vapor deposition (CVD); that is, one or both of steps 302 and steps 303 can be used to dispose one or both of the first contact metal layer and the second contact metal layer on a provided tetrahedrite substrate using PVD or CVD. Methods of providing tetrahedrite substrates (301) are known in the art. Illustratively, the physical vapor deposition can include sputtering or cathodic arc physical vapor deposition. Additionally, or alternatively, the physical vapor deposition can include evaporation. Other exemplary methods of disposing one or both of first contact metal layer and second contact metal layer on the tetrahedrite substrate include, but are not limited to, plating, cladding, and electro-deposition.

In some embodiments, the providing (301) and disposing (302, 303) steps include co-sintering the first contact metal layer and the second contact metal layer in powder form with tetrahedrite powder. For example, such an approach can involve co-sintering the above metals in powder form with tetrahedrite powder in the middle of a sandwich structure, in which case an additive might be mixed with the metal powder to lower the melting point of the metal. Illustratively, a powdered precursor of the tetrahedrite can be loaded into a sintering die, followed by a powdered precursor of the first contact metal layer and a powder precursor of the second contact metal layer. Punches then can be assembled to the sintering die and heat and/or a load can be applied to the die so as to form a structure including the tetrahedrite, the first contact metal layer, and the second contact metal layer. Optionally, before loading the powdered precursor of the tetrahedrite into the sintering die, a powder precursor of the second contact metal layer followed by a powdered precursor of the first contact metal layer can be disposed in the sintering die so as to provide a structure that includes first and second contact metal layers disposed on both sides of the tetrahedrite material.

In some embodiments, the providing (301) and disposing (302, 303) steps include co-sintering thin foils of the first contact metal layer and the second contact metal layer with tetrahedrite powder. For example, a non-limiting embodiment can take the form of co-sintering thin foils of the above metals with tetrahedrite powder in the middle. Illustratively, a powdered precursor of the tetrahedrite can be loaded into a sintering die, followed by a foil of the first contact metal layer and a foil of the second contact metal layer. Punches then can be assembled to the sintering die and heat and/or a load can be applied to the die so as to form a structure including the tetrahedrite, the first contact metal layer, and the second contact metal layer. Optionally, before loading the powdered precursor of the tetrahedrite into the sintering die, a foil of the second contact metal layer followed by a foil of the first contact metal layer can be disposed in the sintering die so as to provide a structure that includes first and second contact metal layers disposed on both sides of the tetrahedrite material.

Note that in some embodiments, surface preparation of metal foils and/or of TE materials (e.g., tetrahedrite) before deposition of metal potentially can be relevant, or a critical factor. For example, foils can be sanded or polished to achieve a desired surface roughness or remove oxides, or both. Additionally, or alternatively, foils can be rinsed in a solvent to dissolve oils prior to bonding or etched in acid to remove oxides of sulfides. In some embodiments, or another embodiment, particle size of the TE material (e.g., tetrahedrite) potentially can be relevant, or a critical factor. For example, the particle sizes of the thermoelectric material can be selected or optimized so as to suit the foil or powder with which it is being cosintered. For example, it can be useful that powders being cosintered have similar particle size as one another. In some embodiments, or another embodiment, density of the TE material (e.g., tetrahedrite) potentially can be relevant, or a critical factor. For example, it can be useful that the tetrahedrite and metal layers are sufficiently dense to function properly.

In some embodiments, process steps to attain metalized thermoelectric material are, or include:

Produce tetrahedrite powder→sinter powder into bulk material→polish bulk pellet→deposit metallization layer(s).

In some embodiments, for the “deposit metallization layer(s)” block, exemplary methods of deposition could be, or include, sputtering, cathodic arc physical vapor deposition (PVD), or any other PVD process. Metal thicknesses could range, for example, from 50 nanometers to 10 microns depending on how the metallic layers are organized.

Methods such as provided herein, e.g., such as described with reference to FIG. 3, suitably can be used to prepare any suitable structure, such as any suitable structure described herein with reference to FIGS. 1A-1C. For example, the first contact metal layer can be, can consist essentially of, or can include a material selected from the group consisting of Ti, Ta, Cr, W, Nb, TiN, Mo, CrNi, and TaN. Additionally, or alternatively, the second contact metal layer can be, can consist essentially of, or can include a material selected from the group consisting of Ag, Ni, Ni/Au, and Ni/Ag. Additionally, or alternatively, the method further can include disposing a diffusion barrier metal layer between the first contact metal layer and the second contact metal layer. For example, the diffusion barrier metal layer can be disposed on the first contact metal layer using any suitable CVD or PVD or other deposition process, followed by disposing the second contact metal layer on the diffusion barrier metal layer. Or, for example, a powder precursor of the diffusion barrier metal layer can be loaded into a sintering die between a powder precursor of the first contact metal layer and a powder precursor of the second contact metal layer. Or, for example, a foil of the diffusion barrier metal layer can be loaded into a sintering die between a foil of the first contact metal layer and a foil of the second contact metal layer. Additionally, or alternatively, the diffusion barrier metal layer can be, can consist essentially of, or can include a material selected from the group consisting of Ti, Ta, Cr, W, Nb, TiN, TaN, CrNi, and Mo. Additionally, or alternatively, the first contact metal layer and diffusion barrier metal layer can be deposited in alternating layers. For example, CVD, PVD, or any other suitable deposition process can be used to alternately deposit the first contact metal layer and the diffusion barrier metal layer. Or, for example, powder precursors of the first contact metal layer and the diffusion barrier metal layer alternately can be loaded into a sintering die. Or, for example, foils of the first contact metal layer and the diffusion barrier metal layer alternately can be loaded into a sintering die. Additionally, or alternatively, the method further can include disposing a braze or solder in direct contact with the second contact metal layer.

As another example, the first contact metal layer can be, can consist essentially of, or can include a material selected from the group consisting of TiW, TiB₂, Y, and MCrAlY where M is Co, Ni, or Fe. Additionally, or alternatively, the second contact metal layer can be, can consist essentially of, or can include a material selected from the group consisting of Ni, Ag, and Au. Additionally, or alternatively, the method can include disposing a diffusion barrier metal layer between the first contact metal layer and the second contact metal layer, e.g., in a manner such as described above. In some embodiments, the diffusion barrier metal layer can be, can consist essentially of, or can include a material selected from the group consisting of Ni, Ti, and W. Additionally, or alternatively, the first contact metal layer and diffusion barrier metal layer can be deposited in alternating layers, e.g., in a manner such as described above. Additionally, or alternatively, the method further can include disposing a braze or solder in direct contact with the second contact metal layer.

As another example, the first contact metal layer can be, can consist essentially of, or can include a material selected from the group consisting of a refractory metal, a refractory metal alloyed with Ti or W, a stable sulfide, a stable sulfide alloyed with Ti or W, a stable refractory metal nitride, and a stable refractory metal carbide. In some embodiments, the refractory metal is selected from the group consisting of Mo, Nb, Ta, W, Re, Ti, V, Cr, Zr, Hf, Ru, Rh, Os, and Ir. In some embodiments, the stable refractory metal nitride is selected from the group consisting of TiN and TaN. In some embodiments, the stable refractory metal carbide is selected from the group consisting of TiC and WC. In some embodiments, the stable sulfide includes La₂S₃. Additionally, or alternatively, the second contact metal layer can be, can consist essentially of, or can include a noble metal. Additionally, or alternatively, the second contact metal layer can be, can consist essentially of, or can include a material selected from the group consisting of Au, Ag, Ni, Ni/Au, and Ni/Ag. Additionally, or alternatively, the method further can include disposing a diffusion barrier metal layer between the first contact metal layer and the second contact metal layer, e.g., in a manner such as described above. In some embodiments, the diffusion barrier metal layer be, can consist essentially of, or can include a material selected from the group consisting of a refractory metal, a refractory metal alloyed with Ti or W, a stable sulfide, a stable nitride, a stable sulfide alloyed with Ti or W, and a stable nitride alloyed with Ti or W. In some embodiments, the refractory metal is selected from the group consisting of Mo, Nb, Ta, W, Re, Ti, V, Cr, Zr, Hf, Ru, Rh, Os, and Ir. In some embodiments, the diffusion barrier metal layer includes a material selected from the group consisting of TiB₂, Ni, and MCrAlY where M is Co, Ni, or Fe. Additionally, or alternatively, the first contact metal layer and diffusion barrier metal layer are deposited in alternating layers, e.g., in a manner such as described above. Additionally, or alternatively, the method further can include disposing a braze or solder in direct contact with the second contact metal layer.

Any of the methods provided herein can be included within a method of making a thermoelectric device, such as a thermoelectric device illustrated in any of FIGS. 2A-2C.

### EXAMPLES

The following examples are intended to be purely illustrative, and not limiting of the present invention.

In a first non-limiting example, structure 100 illustrated in FIG. 1A was prepared using 500 nm of TiW (10% Ti by weight) as first contact metal layer 102, 250 nm of Ni as diffusion barrier metal layer 103, and 250 nm of Au as second contact metal layer 104. In a second non-limiting example, structure 110 illustrated in FIG. 1B was prepared using 500 nm of TiW (10% Ti by weight) as first contact metal layer 112 and 250 nm of Au as second contact metal layer 122. In a third non-limiting example, structure 100 illustrated in FIG. 1A was prepared using 500 nm of TiW (10% Ti by weight) as first contact metal layer 102, 250 nm of Ni as diffusion barrier metal layer 103, and 250 nm of Au followed by 1000 nm of Ag (Au/Ag) as second contact metal layer 104. In a fourth non-limiting example, structure 100 illustrated in FIG. 1A was prepared using 500 nm of TiW (10% Ti by weight) as first contact metal layer 102, 250 nm of Ni as diffusion barrier metal layer 103, and 250 nm of Ag followed by 250 nm of Au (Ag/Au) as second contact metal layer 104. The chemical composition of the tetrahedrite for these four examples was Cu_{12-x-y}NiₓZn_{y}Sb₄S₁₃. The bulk tetrahedrite was formed by measuring stoichiometric amounts of powder, mixing, annealing, and ball milling to react the material. The material then was densified using hot press, sliced and polished into wafers, and metallized using PVD.

The first through fourth examples were subjected to heating tests in which the resulting metallized tetrahedrite structures were heated to 250-400° C. for a length of time ranging from 1 hour to several hundred hours in vacuum or air. Experiments were conducted where metallized tetrahedrite structures were heated prior to soldering them to metal shunts to measure through-plane resistance as well as where the metallized tetrahedrite structures were bonded to metal parts prior to heating and resistance was measured before and after heating. A structure was considered to pass the heating test if the resistance of the structure was less than 10% higher than the resistance of non-metalized tetrahedrite. The first through fourth examples were considered to pass the heating test after 15 hours or more at 400° C. The following table lists metallization stacks that survived at least 15 hours at 400° C. in air:

Metallization stacks that survived at least 15 hrs at 400 C. in air

| | | |
|---|---|---|
| TiW/Ni/Au | 500/250/250 | nm |
| TiW/Ni/Ag/Au | 500/250/250/250 | nm |
| TiW/Au | 500/250 | nm |
| TiW/Ni/Au/Ag | 500/250/250/1000 | nm |

According to some embodiments, a structure includes a tetrahedrite substrate; a first contact metal layer disposed over and in direct contact with the tetrahedrite substrate; and a second contact metal layer disposed over the first contact metal layer. In one example, the structure is described above with reference to FIGS. 1A, 1B, or 1C.

According to some embodiments, a thermoelectric device includes such a structure. In one example, the thermoelectric device is described above with reference to FIGS. 2A, 2B, or 2C.

According to some embodiments, a method includes providing a tetrahedrite substrate; disposing a first contact metal layer over and in direct contact with the tetrahedrite substrate; and disposing a second contact metal layer over the first contact metal layer. In one example, the method is described above with reference to FIG. 3.

According to some embodiments, a method of making a thermoelectric device includes such a method. In one example, the method is described above with reference to FIGS. 2A, 2B, 2C, and/or 3.

Although specific embodiments of the present invention have been described, it will be understood by those of skill in the art that there are other embodiments that are equivalent to the described embodiments. For example, various embodiments and/or examples of the present invention can be combined. Accordingly, it is to be understood that the invention is not to be limited by the specific illustrated embodiments, but only by the scope of the appended claims.

1. A structure, including:
a tetrahedrite substrate;
a first contact metal layer disposed over and in direct contact with the tetrahedrite substrate; and
a second contact metal layer disposed over the first contact metal layer.

2. The structure of claim 1, wherein the first contact metal layer includes a material selected from the group consisting of a refractory metal, a refractory metal alloyed with Ti or W, a stable sulfide, a stable sulfide alloyed with Ti or W, a stable refractory metal nitride, and a stable refractory metal carbide.

3. The structure of claim 2, wherein the refractory metal is selected from the group consisting of Mo, Nb, Ta, W, Re, Ti, V, Cr, Zr, Hf, Ru, Rh, Os, and Ir.

4. The structure of claim 2, wherein the stable refractory metal nitride is selected from the group consisting of TiN and TaN.

5. The structure of claim 2, wherein the stable refractory metal carbide is selected from the group consisting of TiC and WC.

6. The structure of claim 2, wherein the stable sulfide includes La₂S₃.

7. The structure of claim 1, wherein the second contact metal layer includes a noble metal.

8. The structure of claim 1, wherein the second contact metal layer includes a material selected from the group consisting of Au, Ag, Ni, Ni/Au, and Ni/Ag.

9. The structure of claim 1, further including a diffusion barrier metal layer disposed between the first contact metal layer and the second contact metal layer.

10. The structure of claim 9, wherein the diffusion barrier metal layer includes a material selected from the group consisting of a refractory metal, a refractory metal alloyed with Ti or W, a stable sulfide, a stable nitride, a stable sulfide alloyed with Ti or W, and a stable nitride alloyed with Ti or W.

11. The structure of claim 10, wherein the refractory metal is selected from the group consisting of Mo, Nb, Ta, W, Re, Ti, V, Cr, Zr, Hf, Ru, Rh, Os, and Ir.

12. The structure of claim 9, wherein the diffusion barrier metal layer includes a material selected from the group consisting of TiB₂, Ni, and MCrAlY where M is Co, Ni, or Fe.

13. The structure of claim 9, wherein the first contact metal layer and diffusion barrier metal layer are deposited in alternating layers.

14. The structure of claim 1, further including a braze or solder in direct contact with the second contact metal layer.

15. The structure of claim 1, wherein the first contact metal layer includes a material selected from the group consisting of Ti, Ta, Cr, W, Nb, TiN, Mo, CrNi, and TaN.

16. The structure of claim 1, wherein the second contact metal layer includes a material selected from the group consisting of Ag, Ni, Ni/Au, and Ni/Ag.

17. (canceled)

18. The structure of claim 9, wherein the diffusion barrier metal layer includes a material selected from the group consisting of Ti, Ta, Cr, W, Nb, TiN, TaN, CrNi, and Mo.

19. (canceled)

20. (canceled)

21. The structure of claim 1, wherein the first contact metal layer includes a material selected from the group consisting of TiW, TiB₂, Y, and MCrAlY where M is Co, Ni, or Fe.

22. The structure of claim 1, wherein the second contact metal layer includes a material selected from the group consisting of Ni, Ag, and Au.

23. (canceled)

24. The structure of claim 9, wherein the diffusion barrier metal layer includes a material selected from the group consisting of Ni, Ti, and W.

25-56. (canceled)

57. A thermoelectric device including the structure of claim 1.

58. (canceled)
